(19) United States
(12) Patent Application Publication
(10) Pub. No.: US 2002/0163024 A1
(43) Pub. Date: Nov. 7, 2002

(54) Structure and method for fabricating semiconductor structures and devices ultilizing lateral epitaxial overgrowth of a monocrystallaline material layer on a compliant substrate

(75) Inventors: Dirk C. Jordan, Gilbert, AZ (US); Ravindranath Droopad, Chandler, AZ (US); Zhiyi Yu, Gilbert, AZ (US); Corey Overgaard, Phoenix, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Motorola, Inc.

(21) Appl. No.: 09/849,159

(22) Filed: May 4, 2001

(51) Int. Cl. H01L 29/76; H01L 29/94; H01L 31/062; H01L 31/113; H01L 31/119

(52) U.S. Cl. 257/295

(57) ABSTRACT

High quality epitaxial layers of monocrystalline materials can be grown overlying monocrystalline substrates such as large silicon wafers by forming a compliant substrate for growing the monocrystalline layers. One way to achieve the formation of a compliant substrate includes first growing an accommodating buffer layer (24) on a silicon wafer (22). The accommodating buffer layer is lattice matched to both the underlying silicon wafer and the overlying monocrystalline material layer (26). The monocrystalline material layer is epitaxially grown over at least a portion of the accommodating buffer layer via lateral epitaxial overgrowth.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that utilize lateral epitaxial overgrowth of a monocrystalline material layer on a complaint substrate.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality. Defect dislocations resulting from lattice mismatch between the host crystal and grown crystal negatively impact the electrical and optical performance of semiconductor devices formed therefrom.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

One current method of growing materials such as gallium nitride with a reduction in dislocation density is lateral epitaxial overgrowth (“LEO”) on patterned substrates. It has been reported that LEO results in a four to five orders of magnitude reduction of dislocation density in the regions of lateral epitaxial overgrowth compared to the regions of conventional vertical growth. However, LEO of monocrystalline material layers on compliant substrates that provide for lattice compensation between a substrate and the subsequently grown monocrystalline material layer have not been accomplished.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of high quality semiconductor structures, devices and integrated circuits having grown monocrystalline film the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIG. 1 illustrates schematically, in cross section, a device structure in accordance with various embodiments of the invention;

FIGS. 2-4 illustrate schematically, in cross-section, the formation of the device structure illustrated in FIG. 1;

FIGS. 5 and 6 illustrate schematically, in cross section, a device structure in accordance with various embodiments of the invention;

FIG. 7 illustrates graphically the relationship between maximum attainable film thickness and lattice mismatch between a host crystal and a grown crystalline overlayer;

FIGS. 8A-8D illustrate schematically, in cross section, the formation of a device structure in accordance with another embodiment of the invention; and

FIGS. 9A-9C illustrates schematically, in cross section, the formation of yet another embodiment of a device structure in accordance with the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

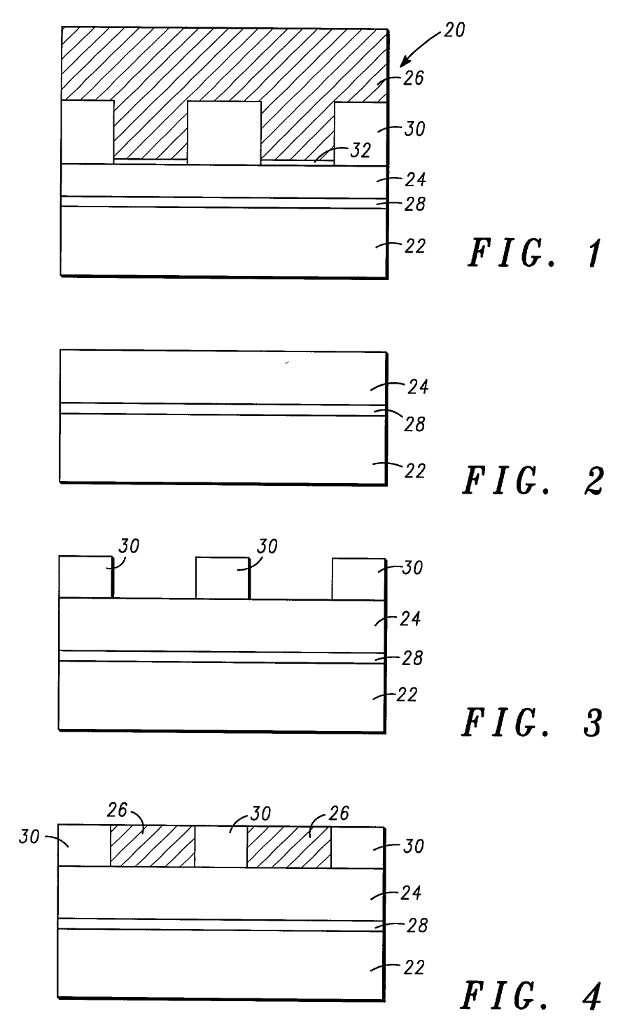

FIG. 1 illustrates schematically, in cross section, a portion of a semiconductor structure 20 in accordance with an embodiment of the invention. Semiconductor structure 20 includes a monocrystalline substrate 22, an accommodating buffer layer 24 comprising a monocrystalline material, patterned features 30, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In another embodiment of the invention, substrate 22 may comprise a (001) Group IV material that has been off-cut towards a (110) direction. The growth of materials on a miscut Si (001) substrate is known in the art. Substrate 22 may be off-cut in the range of from about 2 degrees to about 6 degrees towards the (110) direction. A miscut Group IV substrate reduces dislocations and results in improved quality of subsequently grown layer 24.

In accordance with one embodiment of the invention, structure 20 also includes an amorphous intermediate layer 28 positioned between substrate 22 and accommodating buffer layer 24. In the same or in another embodiment of the invention, structure 20 may also include a template layer 32 formed overlying the accommodating buffer layer 24 between patterned features 30 and underlying monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Referring to FIGS. 2, structure 20 is fabricated by epitaxially growing accommodating buffer layer 24 over substrate 22. Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably, substrate 22 is a wafer containing silicon or germanium, and most preferably is a high quality monocrystalline silicon wafer as used in the semiconductor industry.

Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a unit cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm, and, preferably, has a thickness in the range of approximately 1-2 nm.

Referring to FIG. 3, a dielectric material is then lithographically deposited overlying accommodating buffer layer 24 to form patterned features 30 for subsequent lateral epitaxial overgrowth (“LEO”) processing. Patterned features 30 may be comprised of any suitable dielectric material but are preferably comprised of SiO₂ or Si₂N₃. Patterned features may be of any suitable shape and typically have a width in the range of approximately 1-500 μm, although preferably the width of the patterned fractures has a range of approximately 2-50 μm. The height of patterned features 30 is in the range of approximately 1 nm-10 μm, and preferably is in the range of approximately 10 nm -1 μm. The width of the wells between patterned features 30 is typically in the range of approximately 1-200 μm and is preferably 2-10 μm.

As illustrated in FIG. 4, monocrystalline material layer 26 is then epitaxially grown overlying accommodating buffer layer 24 and between patterned features 30. The monocrystalline material of layer 26 grows vertically to fill the wells between patterned features 30 and then grows laterally over patterned features 30. With this growth process, defect density is reduced, as dislocations present at the interface between the accommodating buffer layer and the monocrystalline material layer cannot propagate beyond the well in the lateral direction, thereby creating a high-quality, relatively defect-free monocrystalline material layer 26, as illustrated in FIG. 1.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (IIIV semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe) and the like. However, monocrystalline material layer 26 may also comprise other semiconductor materials, metals, or non-metal materials that are used in the formation of semiconductor structures, devices and/or integrated circuits.

Appropriate materials for template 32 are discussed below. Suitable template materials chemically bond to the surface of the accommodating buffer layer 24 at selected sites and provide sites for the nucleation of the epitaxial growth of monocrystalline material layer 26. When used, template layer 32 has a thickness ranging from about 1 to about 10 monolayers.

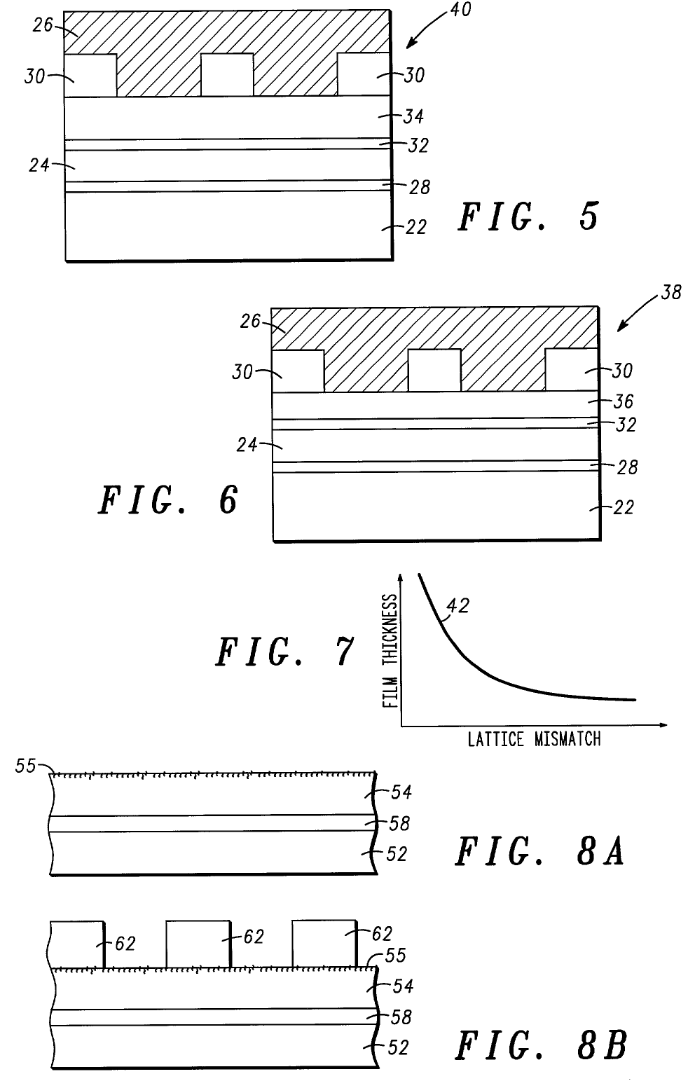

FIG. 5 illustrates, in cross section, a portion of a semiconductor structure 40 in accordance with a further embodiment of the invention. Structure 40 is similar to the previously described semiconductor structure 20, except that an additional buffer layer 34 is positioned between accommodating buffer layer 24 and monocrystalline material layer 26. Specifically, the additional buffer layer is positioned between template layer 32 and the overlying patterned features and layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 6 illustrates, in cross section, a portion of a semiconductor structure 38 in accordance with a further embodiment of the invention. Structure 38 is similar to the previously described semiconductor structure 20, except that a seed layer 36 is positioned between accommodating buffer layer 24 and monocrystalline material layer 26. Specifically, the seed layer is positioned between template layer 32 and the overlying patterned features 30 and layer of monocrystalline material. This seed layer may have a thickness in the range of from 5 nm to 500 nm, but preferably has a thickness in the range of from about 10 nm to about 20 nm. The seed layer serves as a foundation upon which a relatively defect-free monocrystalline layer 26 may grow. While seed layer 36 is illustrated in FIG. 6 as underlying both patterned features 30 and monocrystalline material layer 26, it will be appreciated that seed layer 36, may be deposited after formation of patterned features 30 and, accordingly, may be positioned between patterned features 30 and underlying monocrystalline material layer 26.

The following non-limiting, illustrative examples illustrate various combinations of materials useful in structures 20, 38 and 40 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constant of the subsequently formed layer 26. The accommodating buffer layer can have a thickness of about 2 to about 100 nanometers (nm) and preferably has a thickness of about 3-5 nm. In general, it is desired to have an accommodating buffer layer thick enough to isolate the compound semiconductor layer from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm. Patterned features of Si₂N₃ are lithographically deposited on the accommodating buffer layer to form a pattern suitable for a subsequent lateral epitaxial overgrowth of monocrystalline material to form layer 26.

In accordance with this embodiment of the invention, monocrystalline material layer 26 is a compound semiconductor layer of gallium arsenide (GaAs) or aluminum gallium arsenide (AlGaAs). The thickness of layer 26 generally depends on the application for which the layer is being prepared. To facilitate the epitaxial growth of the GaAs or AlGaAs on the monocrystalline accommodating buffer layer, a template layer is formed by capping the buffer layer prior to or after deposition of the patterned features. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45-30 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. Patterned features are lithographically deposited on the accommodating buffer layer. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown via lateral epitaxial overgrowth on the template layer and over the patterned features. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Patterned features are subsequently lithographically deposited over the accommodating buffer layer. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O), followed by 1-2 monolayers of an excess of zinc followed by the selenidation of zinc on the surface. Alternatively, a template can be, for example, 1-10 monolayers of strontium-sulfur (Sr—S) followed by the ZnSe or ZnSeS. ZnSe or ZnSSe is then epitaxially deposited via lateral epitaxial overgrowth within the wells between the patterned features and then over the features.

### EXAMPLE 4

This embodiment of the invention is an example of structure 40 illustrated in FIG. 5. Substrate 22, accommodating buffer layer 24, patterned features 30 and monocrystalline material layer 26 can be similar to those described in example 1. In addition, an additional buffer layer 34 serves to alleviate any strains that might result from a mismatch of the crystal lattice of the accommodating buffer layer and the lattice of the monocrystalline material which is formed in the wells between the patterned features. Buffer layer 34 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 34 includes a GaAsₓP₁₋ₓ superlattice, wherein the value of x ranges from 0 to 1. In accordance with another aspect, buffer layer 34 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 34 in a like manner. The superlattice can have a thickness of about 50-500 nm and preferably has a thickness of about 100-200 nm. The template for this structure can be the same of that described in example 1. Alternatively, buffer layer 34 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 5. Substrate material 22, accommodating buffer layer 24, patterned features 30, monocrystalline material layer 26 and template layer 32 can be the same as those described above in example 1. In addition, additional buffer layer 34 is inserted between the accommodating buffer layer and the overlying patterned features and monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 34 includes InGaAs, in which the indium composition varies from 0 to about 50%. The buffer layer preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example illustrates materials useful for structure 38 as illustrated in FIG. 6. Substrate material 22, accommodating buffer layer 24, patterned features 30, monocrystalline material layer 26 and template layer 32 can be the same as those described above in example 2. In addition, seed layer 36 is inserted between the accommodating buffer layer and the overlying patterned features and monocrystalline material layer. In accordance with one example of this invention, monocrystalline material layer 26 and seed layer 36 may both comprise GaAs. In an alternative embodiment, seed layer 36 and template layer 32 may be deposited between patterned features 30, which are formed overlying accommodating buffer layer 24.

Referring again to FIG. 1, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 7 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-6, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structure depicted in FIG. 1. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 2° to 6° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface exhibits an ordered 2×1 structure. If an ordered 2×1 structure has not been achieved at this stage of the process, the structure may be exposed to additional strontium until an ordered 2×1 structure is obtained. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 750° C. or higher. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, a dielectric material is lithographically deposited on the template layer via MBE to form patterned features. The patterned features may be comprised of any suitable dielectric material but is preferably comprised of SiO₂ or Si₂N₃. The monocrystalline strontium titanate is then capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer.

Following the formation of the template layer, gallium is subsequently introduced to the reaction with arsenic and GaAs forms. Alternatively, gallium can be deposited on the capping layer to form a Sr—O—Ga bond, and arsenic is subsequently introduced with the gallium to form the GaAs. The GaAs initially grows in the wells between the patterned features and subsequently grows laterally over the patterned features to form layer 26.

The structure illustrated in FIG. 5 can be formed by the process discussed above with the addition of an additional buffer layer deposition step. The additional buffer layer is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, perovskite oxides such as alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

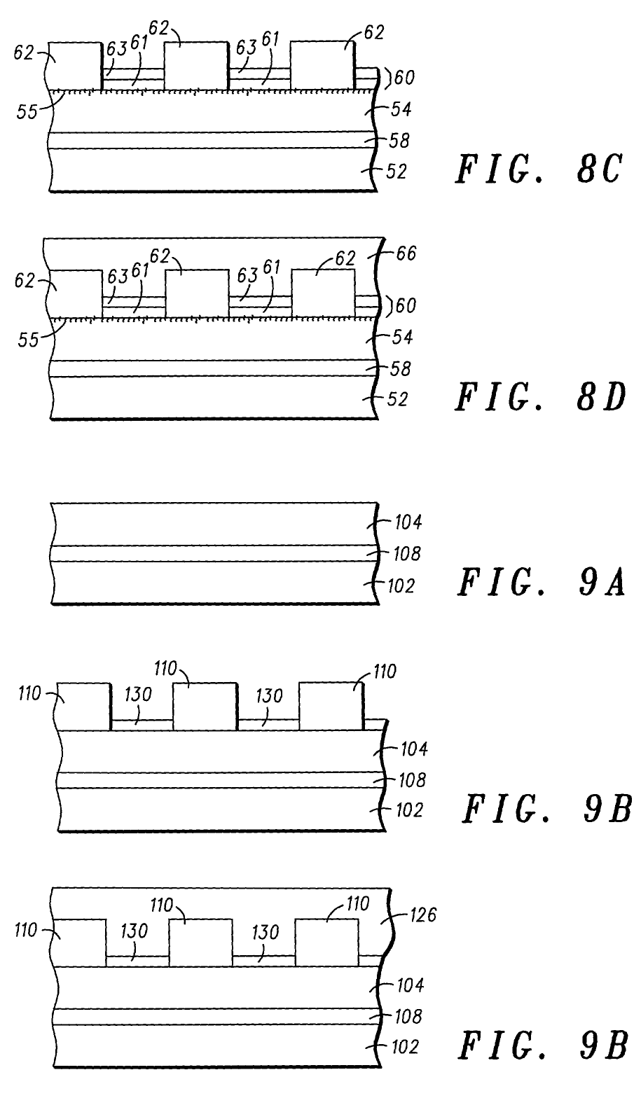

The formation of a device structure in accordance with another embodiment of the invention is illustrated schematically in cross-section in FIGS. 8A-8D. Like the previously described embodiments referred to in FIGS. 1-6, this embodiment of the invention involves the process of forming a compliant substrate utilizing the epitaxial growth of single crystal oxides, such as the formation of accommodating buffer layer 24 previously described with reference to FIG. 1, the formation of a template layer 30 and the deposition of monocrystalline material layer 26 by lateral epitaxial overgrowth over patterned features. However, the embodiment illustrated in FIGS. 8A-8D utilizes a template that includes a surfactant to facilitate layer-by-layer monocrystalline material growth.

Turning now to FIG. 8A, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-6. Layer 54 is grown with a strontium (Sr) terminated surface represented in FIG. 8A by hatched line 55. Patterned features 62 are lithographically deposited on accommodating buffer layer 54, as illustrated in FIG. 8B. In this exemplary embodiment, patterned features 62 may be formed of SiO₂.

A template layer 60 which includes a surfactant layer 61 and capping layer 63, as illustrated in FIG. 8C, is then formed overlying accommodating buffer layer 54 between patterned features 62. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one quarter to two monolayers, over layer 54 as illustrated in FIG. 8C by way of MBE, although other epitaxial processes may also be performed including CVD, MOCVD, MEE, ALE, PVD, CSD, PLD, or the like.

Surfactant layer 61 is then exposed to a Group V element such as arsenic, for example, to form capping layer 63 as illustrated in FIG. 8C. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited by LEO via MBE, CVD, MOCVD, MEE, ALE, PVD, CSD, PLD and the like. Monocrystalline material layer 66 is first grown in the wells between patterned features 62 and then grows laterally over patterned features 62 to form the final structure illustrated in FIG. 8D.

FIGS. 9A-9C schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two-dimensional layer by layer growth.

The structure illustrated in FIG. 9A includes a monocrystalline substrate 102, an amorphous interface layer 108 and an accommodating buffer layer 104. Amorphous intermediate layer 108 is grown on substrate 102 at the interface between substrate 102 and accommodating buffer layer 104, as previously described with reference to FIGS. 1-6. Substrate 102 is preferably silicon but may also comprise any of those materials previously described with reference to substrate 22 in FIGS. 1-6, and accompanying buffer layer is preferably a strontium barium titanate layer, but may include any of the materials described above in connection with layer 24 in FIGS. 1-6. Amorphous interface layer 108 may comprise any of those materials previously described with reference to amorphous interface layer 28 in FIGS. 1-6 but preferably comprises a silicon oxide. Patterned features 110 are then lithographically deposited on accommodating buffer layer 104, as illustrated in FIG. 9B. In this exemplary embodiment, patterned features 110 may be formed of SiO₂.

A template layer 130 is deposited over accommodating buffer layer 104 and between patterned features 110, as illustrated in FIG. 9B and preferably comprises a thin layer of Zintl-type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

Monocrystalline material layer 126 is then grown by LEO via MBE, CVD, MOCVD, MEE, ALE, PVD, CSD, PLD and the like to form the final structure illustrated in FIG. 8C. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl-type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions are meant to illustrate embodiments of the present invention and not limit the present invention. There are a multiplicity of other combinations and other embodiments of the present invention. For example, the present invention includes structures and methods for fabricating material layers that form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 75 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate;
an accommodating buffer layer epitaxially grown overlying said substrate; and
a monocrystalline material layer which is grown via lateral epitaxial overgrowth processing and which overlies at least a portion of said accommodating buffer layer.

2. The semiconductor structure of claim 1, further comprising an amorphous oxide layer underlying the accommodating buffer layer.

3. The semiconductor structure of claim 1, wherein the substrate comprises silicon.

4. The semiconductor structure of claim 1, wherein the accommodating buffer layer comprises an oxide selected from the group consisting of alkaline earth metal titanates, alkaline earth metal zirconates, alkaline earth metal hafnates, alkaline earth metal tantalates, alkaline earth metal ruthenates, and alkaline earth metal niobates.

5. The semiconductor structure of claim 1, wherein said accommodating buffer layer comprises SrₓB₁₋ₓTiO₃, where x ranges from 0 to 1.

6. The semiconductor structure of claim 1, further comprising a plurality of patterned features which are formed of a dielectric material and which overlie said accommodating buffer layer.

7. The semiconductor structure of claim 6, wherein said plurality of patterned features is formed of material selected from the group comprising SiO₂ and SiNₓ, where x is greater than 0.

8. The semiconductor structure of claim 6, wherein said plurality of patterned features is lithographically deposited.

9. The semiconductor structure of claim 1, wherein said monocrystalline material layer comprises at least one of a semiconductor material, a compound semiconductor material, a metal and a non-metal.

10. The semiconductor structure of claim 1, further comprising a template layer formed overlying at least a portion of said accommodating buffer layer and between said plurality of patterned features.

11. The semiconductor structure of claim 10, wherein the template layer comprises a Zintl-type phase material.

12. The semiconductor structure of claim 11, wherein the Zintl-type phase material comprises at least one of SrAl₂, (MgCaYb)Ga₂, (Ca,Sr,Eu,Yb)In₂, BaGe₂As, and SrSn₂As₂.

13. The semiconductor structure of claim 10, wherein the template layer comprises a surfactant material.

14. The semiconductor structure of claim 13, wherein the surfactant comprises at least one of Al, In, and Ga.

15. The semiconductor structure of claim 13, wherein the template layer further comprises a capping layer.

16. The semiconductor structure of claim 15, wherein the capping layer is formed by exposing said surfactant material to a cap-inducing material.

17. The semiconductor structure of claim 16, wherein the cap-inducing material comprises at least one of As, P, Sb, and N.

18. The semiconductor structure of claim 15, wherein the surfactant comprises Al, the capping layer comprises Al₂Sr, and the monocrystalline material layer comprises GaAs.

19. The semiconductor structure of claim 1, wherein said substrate is characterized by a first lattice constant and the monocrystalline material layer is characterized by a second lattice constant different than the first lattice constant.

20. The semiconductor structure of claim 19, wherein the accommodating buffer layer is characterized by a third lattice constant different than the second lattice constant.

21. The semiconductor structure of claim 1, wherein said substrate comprises silicon and said amorphous oxide layer comprises a silicon oxide.

22. The semiconductor structure of claim 1, wherein the monocrystalline material layer comprises a material selected from the group consisting of GaAs, GaAlAs, GaInAs, InP, CdS, CdHgTe, InGaP, ZnSe, ZnSeS, PbSe, PbTe, and PbSSe.

23. The semiconductor structure of claim 1, wherein said accommodating buffer layer has a thickness of about 2-100 nm.

27. The semiconductor structure of claim 25, wherein the amorphous oxide layer has thickness of about 0.5-5 nm.

28. The semiconductor structure of claim 1, further comprising an additional buffer layer epitaxially grown overlying said accommodating buffer layer and underlying said monocrystalline material layer.

29. The semiconductor structure of claim 28, wherein the additional buffer layer comprises at least one of a semiconductor material, a compound semiconductor material, a metal and a non-metal.

30. The semiconductor structure of claim 28, further comprising a plurality of patterned features which are formed of a dielectric material and which overlie said additional buffer layer.

31. The semiconductor structure of claim 30, wherein said plurality of patterned features is formed of material selected from the group comprising SiO₂ and SiNₓ, where x is greater than 0.

32. The semiconductor structure of claim 28 wherein said additional buffer layer comprises a material selected from the group consisting of GaAs, GaAlAs, GaInAs, InP, CdS, CdHgTe, InGaP, ZnSe, ZnSeS, PbSe, PbTe, and PbSSe.

33. A process for fabricating a semiconductor device structure comprising:
providing a monocrystalline substrate;
epitaxially growing an accommodating buffer layer overlying said substrate;
depositing a plurality of patterned features overlying said accommodating buffer layer; and
epitaxially growing a monocrystalline material layer overlying at least portions of said accommodating buffer layer and said patterned features.

34. The process of claim 33, further comprising forming an amorphous intermediate layer between said substrate and said accommodating buffer layer.

35. The process of claim 33, further comprising forming a template layer overlying said accommodating buffer layer and between said patterned features;

36. The process of claim 33, wherein said providing a monocrystalline substrate comprises providing a substrate formed of silicon.

37. The process of claim 33, wherein said epitaxially growing an accommodating buffer layer comprises epitaxially growing an accommodating buffer layer formed of an oxide selected from the group consisting of alkaline earth metal titanates, alkaline earth metal zirconates, alkaline earth metal hafnates, alkaline earth metal tantalates, alkaline earth metal ruthenates, and alkaline earth metal niobates.

38. The process of claim 37, wherein said epitaxially growing an accommodating buffer layer comprises epitaxially growing an accommodating buffer layer formed of SrₓBa₁₋ₓTiO₃, where x ranges from 0 to 1.

39. The process of claim 33, wherein said epitaxially growing a monocrystalline material layer comprises epitaxially growing a monocrystalline material layer formed of at least one of a semiconductor material, a compound semiconductor material, a metal and a non-metal.

40. The process of claim 33, wherein said epitaxially growing a monocrystalline material layer comprises epitaxially growing a monocrystalline material layer formed of a material selected from the group consisting of GaAs, GaAlAs, GaInAs, InP, CdS, CdHgTe, InGaP, ZnSe, ZnSeS, PbSe, PbTe, and PbSSe.

41. The process of claim 33, wherein each of said epitaxially growing comprises epitaxially growing by a process selected from the group consisting of MBE, MOCVD, MEE, CVD, PVD, PLD, CSD, and ALE.

42. The process of claim 33, wherein said depositing a plurality of patterned features comprises depositing a plurality of patterned features formed of material selected from the group comprising SiO₂ and SiNₓ, where x is greater than 0.

43. The process of claim 33, wherein said depositing a plurality of patterned features comprises lithographically depositing a plurality of patterned features.

44. The process of claim 33, further comprising forming a template layer overlying at least a portion of said accommodating buffer layer and between said plurality of patterned features.

45. The process of claim 44, wherein said forming a template layer comprises forming a template layer of Zintl-type phase material.

46. The process of claim 45, wherein said forming a template layer of Zintl-ype phase material comprises forming a template layer of at least one of SrAl₂, (MgCaYb) Ga₂, (Ca, Sr, Eu, Yb)In₂, BaGe₂As, and SrSn₂As₂.

47. The process of claim 44, wherein said forming a template layer comprises forming a template layer of surfactant material.

48. The process of claim 47, wherein said forming a template layer of surfactant material comprises forming a template layer of at least one of Al, In, and Ga.

49. The process of claim 47, wherein said forming a template layer comprises forming a template layer having a capping layer.

50. The process of claim 49, wherein said forming a template layer having a capping layer comprises exposing said surfactant material to a cap-inducing material.

51. The process of claim 50, wherein said exposing said surfactant material to a cap-inducing material comprises exposing said surfactant material to at least one of As, P, Sb and N.

52. The process of claim 33, further comprising forming an additional buffer layer overlying said accommodating buffer layer and underlying said plurality of patterned features.

53. The process of claim 52, wherein said forming an additional buffer layer comprises forming an additional buffer layer of at least one of a semiconductor material, a compound semiconductor material, a metal and a non-metal.

54. The process of claim 33, further comprising growing a seed layer overlying at least a portion of said accommodating buffer layer.

55. The process of claim 33, wherein said epitaxially growing a monocrystalline material layer comprises epitaxially growing a monocrystalline material layer by lateral epitaxial overgrowth processing.
